(19) United States
(12) Patent Application Publication
(10) Pub. No.: US 2025/0197196 A1
(43) Pub. Date: Jun. 19, 2025

(54) PACKAGING FOR MICRO-ELECTROMECHANICAL SYSTEM (MEMS) DEVICE

(71) Applicant: QUALCOMM Incorporated, San Diego, CA (US)

(72) Inventors: Emre TOPAL, München (DE); Andreas FRANZ, Vaterstetten (DE); Anna Katharina KREFFT, Haar (DE); Rodrigo PACHER FERNANDES, Deutschlandsberg (AT)

(21) Appl. No.: 18/542,156

(22) Filed: Dec. 15, 2023

(51) Int. Cl. B81B 7/00; B81C 1/00

(52) U.S. Cl. CPC B81B 7/0041; B81C 1/00293; B81C 2203/0154; B81C 2203/019

(57) ABSTRACT

In an aspect, a micro-electromechanical system (MEMS) device includes a substrate, a MEMS die mounted on the substrate, a sealing structure, and a conductive shielding structure over the substrate and covering the MEMS die and the sealing structure. The MEMS die may include a functional structure and an outer frame structure. The conductive shielding structure, the sealing structure, and the substrate may define an inner space of the MEMS device, where the sealing structure may be configured to block movement of air or a molding compound from the inner space to the functional structure of the MEMS die.

### TECHNICAL FIELD

The present disclosure generally relates to packaging for a micro-electromechanical system (MEMS) device, and more particularly to advanced MEMS packaging having a sealing structure.

### BACKGROUND

A micro-electromechanical system (MEMS) device corresponds to a device that incorporates a MEMS die. The MEMS die may include miniaturized electronic components and mechanical components, which may be implemented based on a combination of various manufacturing processes including deposition, lithography, etching, and/or polishing. In some aspects, a MEMS die may be configured as a transducer that can convert energy received in one form (e.g., optical, acoustic, magnetic, electrical, gravitational, kinetic, chemical, and/or biological) into output electrical signals, and/or as an actuator for moving miniaturized components (e.g., lens, mirrors, levers, and/or gears) based on input electrical signals. In some examples, a MEMS die may include a functional structure where moving parts may be disposed and may include an outer frame structure that is configured to mechanically support the functional structure.

FIG. 1 illustrates a micro-electromechanical system (MEMS) device 100 that is known to a person in the related art. FIG. 1 is a cross-sectional view of the MEMS device 100, and certain details of the MEMS device 100 may be simplified or omitted.

As shown in FIG. 1, the MEMS device 100 may include a substrate 110 and a MEMS die 120 mounted on the substrate 110. The MEMS die 120 may include a functional structure 122 and an outer frame structure 124 that is configured to mechanically support the functional structure 122. The MEMS device 100 may include an integrated circuit (IC) die 130 mounted on the substrate 110. Also, the MEMS device 100 may include a conductive cover 150 disposed on the substrate 110.

The MEMS die 120 may include conductive terminals 126 on the outer frame structure 124. The IC die 130 may include first conductive terminals 132 and second conductive terminals 134. The substrate 110 may include conductive terminals 112 formed thereon. Moreover, the conductive terminals 126 of the MEMS die 120 and the first conductive terminals 132 of the IC die 130 are connected by bond wires 142, and the second conductive terminals 134 of the IC die 130 and the conductive terminals 112 on the substrate 110 are connected by bond wires 144. In some examples, additional conductive terminals (not shown) may be formed under the substrate 110 and configured for connecting the MEMS device 100 to an external component (e.g., a circuit board).

In some applications, for the MEMS device 100 based on a wire bonding process for connecting various dies and the substrate, it may be challenging to further reduce the size of the overall package and/or to add passive components therein within a size constraint. In some applications, it may also be desirable to prevent contaminants entering into the functional structure 122 of the MEMS die 120 from other parts of the MEMS device 100 during manufacturing of the MEMS device 100 or during operation of the MEMS device 100.

Accordingly, there is a need for a MEMS device with improved package configurations and methods of manufacturing such MEMS device to address the above-noted issues.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, a micro-electromechanical system (MEMS) device includes a substrate; a MEMS die mounted on the substrate, the MEMS die including a functional structure and an outer frame structure; a sealing structure; and a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space to the functional structure of the MEMS die.

In an aspect, a method of manufacturing a micro-electromechanical system (MEMS) device includes mounting a MEMS die on a substrate, the MEMS die including a functional structure and an outer frame structure; forming a sealing structure; and forming a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space through the sealing structure to the functional structure of the MEMS die.

In an aspect, an electronic device includes a micro-electromechanical system (MEMS) device that comprises: a substrate; a MEMS die mounted on the substrate, the MEMS die including a functional structure and an outer frame structure; a sealing structure; and a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space through the sealing structure to the functional structure of the MEMS die.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a micro-electromechanical system (MEMS) device.

FIGS. 2A-2B illustrate MEMS device examples, according to aspects of the disclosure.

FIGS. 3A-3B illustrate sealing structure examples, according to aspects of the disclosure.

FIGS. 4A-4B illustrate MEMS device examples, according to aspects of the disclosure.

FIG. 5 illustrates another MEMS device example, according to aspects of the disclosure.

FIGS. 6A-6E illustrate MEMS device examples that may be variations of the example of FIG. 2A, according to aspects of the disclosure.

FIGS. 7A-7B illustrate MEMS device examples that may be variations of the example of FIG. 4A, according to aspects of the disclosure.

FIGS. 8A-8B illustrate MEMS device examples that may be variations of the example of FIG. 5, according to aspects of the disclosure.

FIGS. 9A-9C illustrate yet another MEMS device examples that may be variations of the example of FIG. 2A, according to aspects of the disclosure.

FIGS. 10A-10B illustrate MEMS device examples that may be variations of the example of FIG. 4A, according to aspects of the disclosure.

FIGS. 11A-11D illustrate MEMS device examples that may be variations of the example of FIG. 5, according to aspects of the disclosure.

FIGS. 12A-12E illustrate structures at various stages of manufacturing a MEMS device example, such as the example of FIG. 2A, according to aspects of the disclosure.

FIG. 12F in view of FIGS. 12A-12C illustrate structures at various stages of manufacturing a MEMS device example, such as the example of FIG. 2B, according to aspects of the disclosure.

FIGS. 13A-13C illustrate structures at various stages of manufacturing a MEMS device example, such as the example of FIG. 4A, according to aspects of the disclosure.

FIGS. 14A-14C illustrate structures at various stages of manufacturing a MEMS device example, such as the example of FIG. 5, according to aspects of the disclosure.

FIG. 15 illustrates a method of manufacturing a MEMS device, according to aspects of the disclosure.

FIG. 16 illustrates a mobile device, according to aspects of the disclosure.

FIG. 17 illustrates various electronic devices that may incorporate a MEMS device described herein, according to aspects of the disclosure.

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the disclosure are provided in the following description and related drawings directed to various examples provided for illustration purposes. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

In certain described example implementations, instances are identified where various component structures and portions of operations can be taken from known, conventional techniques, and then arranged in accordance with one or more aspects. In such instances, internal details of the known, conventional component structures and/or portions of operations may be omitted to help avoid potential obfuscation of the concepts illustrated in the illustrative aspects disclosed herein.

The terminology used herein is for the purpose of describing particular aspects only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. Additionally, terms such as approximately, generally, and the like indicate that the examples provided are not intended to be limited to the precise numerical values or geometric shapes and include normal variations due to, manufacturing tolerances and variations, material variations, and other design considerations.

As noted in the foregoing, various aspects relate generally to manufacturing a MEMS device that includes a MEMS die and a sealing structure, where the sealing structure may be configured to block movement of air, a molding compound, and/or a contaminant from an inner space of the MEMS device to a functional structure of the MEMS die. Accordingly, packaging a MEMS die based on a surface mount technology (SMT) and molding encapsulation may be implemented with the introduction of the sealing structure. In contrast, other approaches may rely upon chip attach and wire bonding process for assembly, and the resulting packages may not be encapsulated by a molding material. Also, other approaches may require the passive components to be embedded in the substrate or provided separately from the MEMS device.

Particular aspects of the subject matter described in this disclosure can be implemented to realize one or more of the following potential advantages. In some examples, the sealing structure may include a metal ring that can be formed together with a conductive pattern or terminal, or a polymer ring that can be formed together with forming a solder resist structure, and thus does not further complicate the manufacturing process of the MEMS device. In some aspects, the sealing structure may include one or more sealing foils or one or more sheet molding layers, which can still minimize the complexity added to the manufacturing process of the MEMS device. Also, the passive components can be incorporated into the MEMS device based on SMT. Accordingly, the MEMS device may be manufactured in a smaller size and can be encapsulated by a molding material for better contamination and/or moisture resistance with a low manufacturing cost. In contrast, the MEMS devices based on other approaches usually lead to a larger size and a higher manufacturing cost.

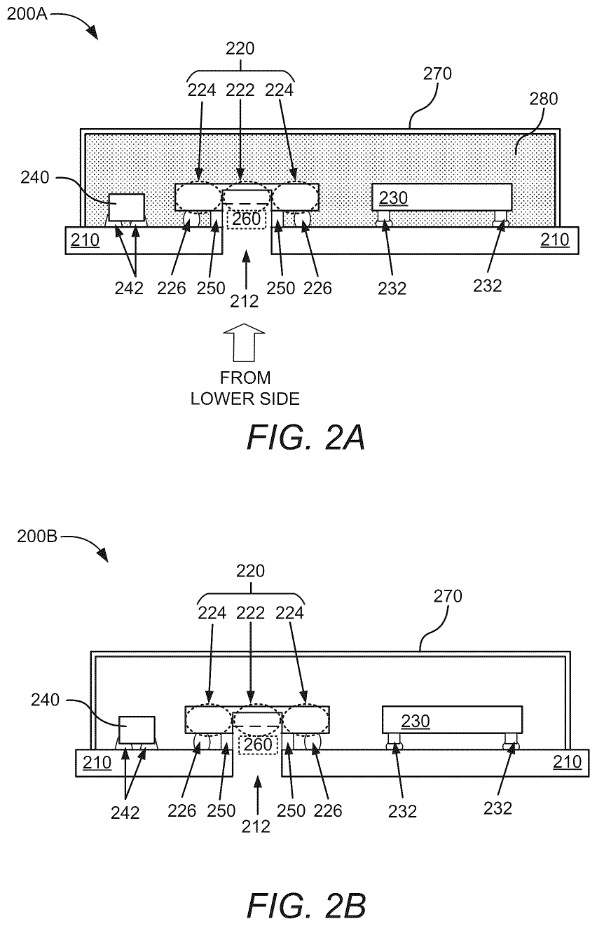

FIG. 2A illustrates a MEMS device example 200A, according to aspects of the disclosure. FIG. 2A is a cross-sectional view of the MEMS device example 200A, and certain details of the MEMS device example 200A may be simplified or omitted.

As shown in FIG. 2A, the MEMS device example 200A may include a substrate 210 and a MEMS die 220 mounted on the substrate 210. The MEMS die 220 may include a functional structure 222 and an outer frame structure 224. In some aspects, the functional structure 222 may include moving parts of the MEMS die 220, and the outer frame structure 224 may be configured to mechanically support the functional structure 222. In some aspects, the MEMS die 220 may be mounted on the substrate 210 through one or more conductive terminals 226 (e.g., solder bumps or copper pillar bumps) based on SMT.

The MEMS device example 200A may include an integrated circuit (IC) die 230 and a passive component 240 mounted on the substrate 210. In some aspects, the IC die 230 and the passive component 240 may be mounted on the substrate 210 through one or more conductive terminals 232 and 242 (e.g., solder bumps or copper pillar bumps) based on SMT. In some aspects, the substrate 210 may include conductive patterns, such as conductive traces and vias, formed therein for electrically connecting various conductive terminals on an upper surface of the substrate 210 to conductive terminals on a lower surface of the substrate 210 (not shown in FIG. 2A). In some aspects, the conductive terminals (not shown) formed on the lower surface of the substrate 210 may be configured for connecting the MEMS device example 200A to an external component (e.g., a circuit board).

For example, the MEMS die 220 may be electrically coupled to the substrate 210 through the one or more conductive terminals 226 (e.g., one or more solder bumps or copper pillar bumps) between the MEMS die 220 and the substrate 210. In some aspects, the IC die 230 may be electrically coupled to the MEMS die 220 through one or more conductive terminals 234 (e.g., one or more solder bumps or copper pillar bumps) and/or one or more conductive posts 236 (e.g., copper posts) between the MEMS die 220 and the substrate 210, one or more conductive terminals 232 (e.g., one or more solder bumps or copper pillar bumps) between the IC die 230 and the substrate 210, and one or more conductive patterns in the substrate 210.

The MEMS device example 200A may include a sealing structure 250 between the MEMS die 220 and the substrate 210. In some aspects, the sealing structure 250 may be coupled to the outer frame structure 224 of the MEMS die 220 and the substrate 210. In some aspects, the sealing structure 250 may be configured to define an access channel 260 through which the functional structure 222 may be accessible from outside of the MEMS device example 200A. In some aspects, the substrate 210 may include an opening 212 communicatively coupled with the access channel 260 such that the functional structure 222 may be accessible from a lower side the MEMS die 220. In some aspects, the substrate 210 may not include the opening 212, and the functional structure 222 of the MEMS die 220 may not be accessible from the lower side of the MEMS die 220.

The MEMS device example 200A may include a conductive shielding structure 270 over the substrate 210 and covering the MEMS die 220. In some aspects, the conductive shielding structure 270, the sealing structure 250, and the substrate 210 may define an inner space of the MEMS device example 200A. In some aspects, the sealing structure 250 may be configured to block movement of air, a molding compound, and/or any contaminants from the inner space to the functional structure 222 of the MEMS die 220.

In some aspects, the MEMS device example 200A may have a molding compound portion 280 that includes a molding compound disposed in at least a portion of the inner space. In some aspects, the conductive shielding structure 270 may be conductive lines, a conductive mesh, or a conductive film over the molding compound portion 280. In some aspects, the conductive shielding structure 270 may be a conductive cover mounted on the substrate 210. In some aspects, the molding compound portion 280 may be disposed based on compression molding. In some aspects, the sealing structure 250 may prevent the movement of the molding compound from the inner space to the functional structure 222 during a compression molding process.

FIG. 2B illustrates another MEMS device example 200B, according to aspects of the disclosure. FIG. 2B is a cross-sectional view of the MEMS device example 200B, and certain details of the MEMS device example 200B may be simplified or omitted. Also, the MEMS device example 200B may be a variation of the MEMS device example 200A. Accordingly, components in FIG. 2B that are the same or similar to those in FIG. 2A are given the same reference numbers, and detailed description thereof may be omitted.

As shown in FIG. 2B, compared with the MEMS device example 200A, the MEMS device example 200B does not include the molding compound portion 280. In some aspects, the conductive shielding structure 270 may be a conductive cover mounted on the substrate 210. In some aspects, the sealing structure 250 may prevent the movement of air or any contaminants from the inner space to the functional structure 222 during manufacturing of the MEMS device example 200B or even during the operation of the finished MEMS device 200B.

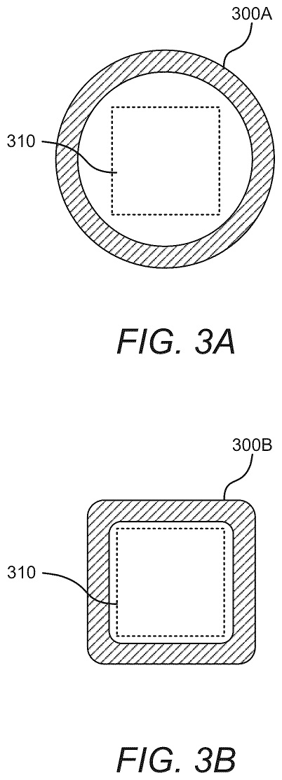

FIGS. 3A-3B illustrate sealing structure examples 300A and 300B, according to aspects of the disclosure. In some aspects, any of the sealing structure examples 300A and 300B may correspond to the sealing structure 250 in FIGS. 2A and 2B, and/or any other sealing structures described in this disclosure.

In some aspects, FIG. 3A may correspond to a top view of the sealing structure example 300A. As shown in FIG. 3A, the sealing structure example 300A may surround a projection 310 of a functional structure of a corresponding MEMS die (e.g., the functional structure 222 of the MEMS die 220). Also, FIG. 3B may correspond to a top view of the sealing structure example 300B. As shown in FIG. 3B, the sealing structure example 300B may surround a projection 310 of a functional structure of a corresponding MEMS die (e.g., the functional structure 222 of the MEMS die 220).

In some aspects, the sealing structure may have a round shape (e.g., the sealing structure example 300A), a rounded square shape (e.g., the sealing structure example 300B), a square shape, a hexagon shape, an octagon shape, or any other suitable shape. In some aspects, the sealing structure may include a metal material (e.g., copper), a polymer material (e.g., an adhesive material or a solder resist material), or any other suitable material that may be configured to block the movement of air or a molding compound.

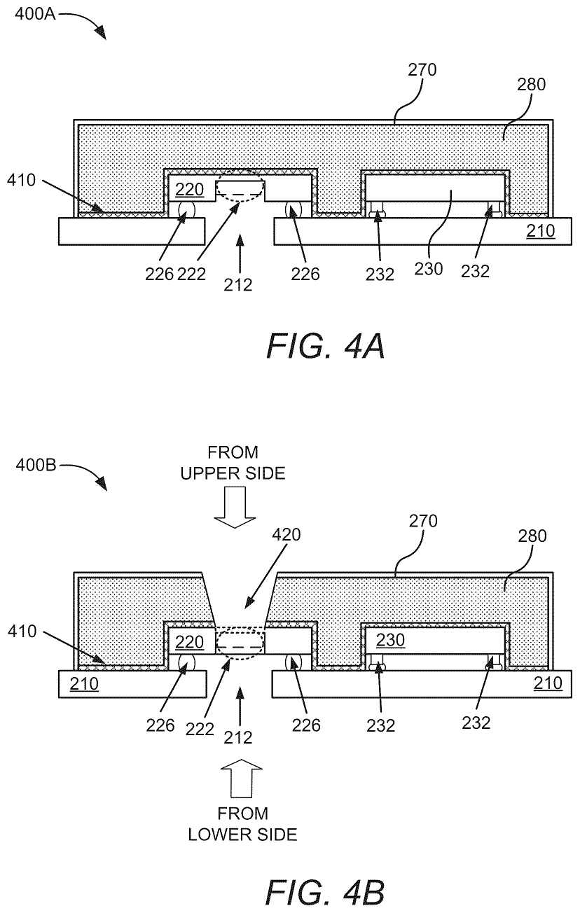

FIG. 4A illustrates a MEMS device example 400A, according to aspects of the disclosure. FIG. 4A is a cross-sectional view of the MEMS device example 400A, and certain details of the MEMS device example 400A may be simplified or omitted. Also, components in FIG. 4A that are the same or similar to those in FIG. 2A are given the same reference numbers, and detailed description thereof may be omitted.

As shown in FIG. 4A, compared with the MEMS device example 200A, the MEMS device example 400A does not include the sealing structure 250 between the MEMS die 220 and the substrate 210. Instead, the MEMS device example 400A may include a sealing structure 410 that may include one or more sealing foils covering the MEMS die 220, at least a portion of the substrate 210 surrounding the MEMS die 220, and/or the IC die 230. In some aspects, the sealing structure 410 may not cover the IC die 230, and the IC die 230 may be underfilled by a molding compound. In some aspects, the MEMS device example 400A may include the molding compound portion 280, which may be disposed based on compression molding. In some aspects, the sealing structure 410 may prevent the movement of the molding compound from the inner space defined by the sealing structure 410 and the conductive shielding structure 270 to the functional structure 222 during a compression molding process.

While FIG. 4A does not show the passive component 240, the MEMS device example 400A may still have one or more passive components mounted on the substrate 210.

FIG. 4B illustrates another MEMS device example 400B, according to aspects of the disclosure. FIG. 4B is a cross-sectional view of the MEMS device example 400B, and certain details of the MEMS device example 400B may be simplified or omitted. Also, the MEMS device example 400B may be a variation of the MEMS device example 400A. Accordingly, components in FIG. 4B that are the same or similar to those in FIG. 4A are given the same reference numbers, and detailed description thereof may be omitted.

As shown in FIG. 4B, compared with the MEMS device example 400A, the MEMS device example 400B may further include an opening 420 that is configured to expose the functional structure 222 such that the functional structure 222 of the MEMS die 220 may be accessible from an upper side of the MEMS die 220. In some aspects, the opening 420 may be formed based on a laser drilling process punching through the conductive shielding structure 270 and the molding compound portion 280 after they are formed.

In FIG. 4B, the functional structure 222 of the MEMS die 220 may be accessible from a lower side of the MEMS die 220 through an opening 212 of the substrate 210 as illustrated with reference to FIG. 2A. In some aspects, the substrate 210 may not include the opening 212, and the functional structure 222 of the MEMS die 220 may not be accessible from the lower side of the MEMS die 220.

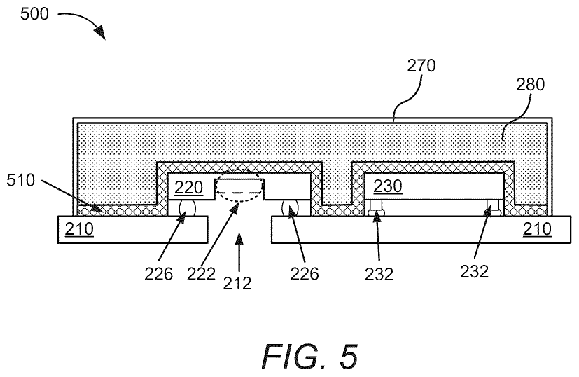

FIG. 5 illustrates a MEMS device example 500, according to aspects of the disclosure. FIG. 5 is a cross-sectional view of the MEMS device example 500, and certain details of the MEMS device example 500 may be simplified or omitted. Also, components in FIG. 5 that are the same or similar to those in FIG. 2A are given the same reference numbers, and detailed description thereof may be omitted.

As shown in FIG. 5, compared with the MEMS device example 200A, the MEMS device example 500 does not include the sealing structure 250 between the MEMS die 220 and the substrate 210. Instead, the MEMS device example 500 may include a sealing structure 510 that may include one or more sheet molding layers covering the MEMS die 220, and at least a portion of the substrate 210 surrounding the MEMS die 220, and/or the IC die 230. In some aspects, the sealing structure 510 may not cover the IC die 230, and the IC die 230 may be underfilled by a molding compound. In some aspects, the MEMS device example 500 may include the molding compound portion 280, which may be disposed based on compression molding or sheet molding with another one or more sheet molding layers. In some aspects, the sealing structure 510 may prevent the movement of the molding compound from the inner space defined by the sealing structure 510 and the conductive shielding structure 270 to the functional structure 222 during a compression molding process or a sheet molding.

While FIG. 5 does not show the passive component 240, the MEMS device, for example 500 may still have one or more passive components mounted on the substrate 210. Also, in some aspects, an opening similar to the opening 420 may be formed to make the functional structure 222 of the MEMS die 220 accessible from an upper side of the MEMS die 220.

In some aspects, the MEMS device examples shown in FIGS. 2A, 2B, 4A, 4B, and 5 correspond to having a MEMS die and an IC die disposed side-by-side on a substrate. Accordingly, the MEMS device examples shown in FIGS. 2A, 2B, 4A, 4B, and 5 may also be referred to as based on 2D packaging (where D may stand for “dimensions”).

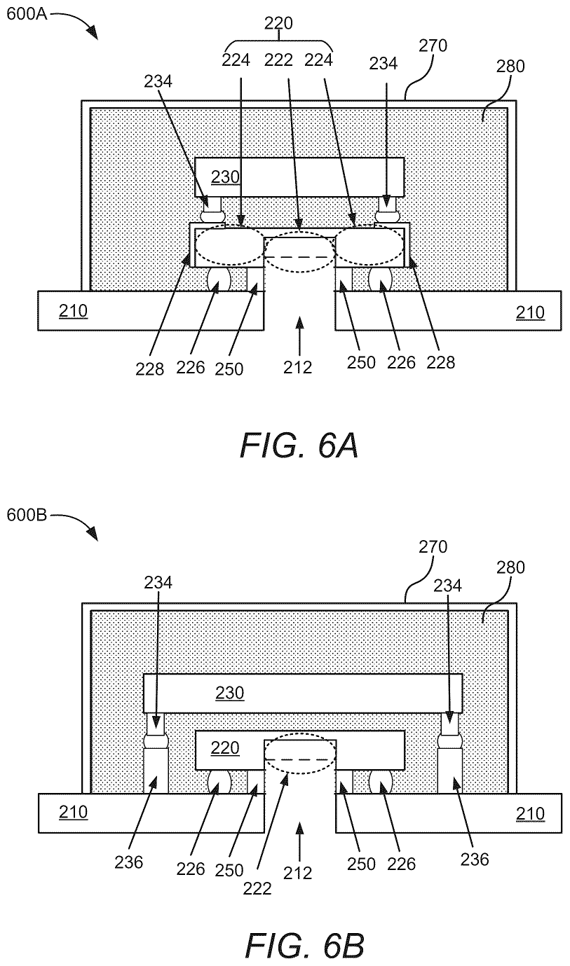

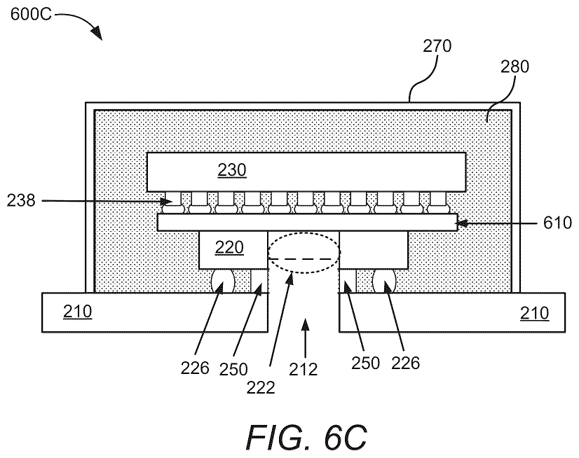

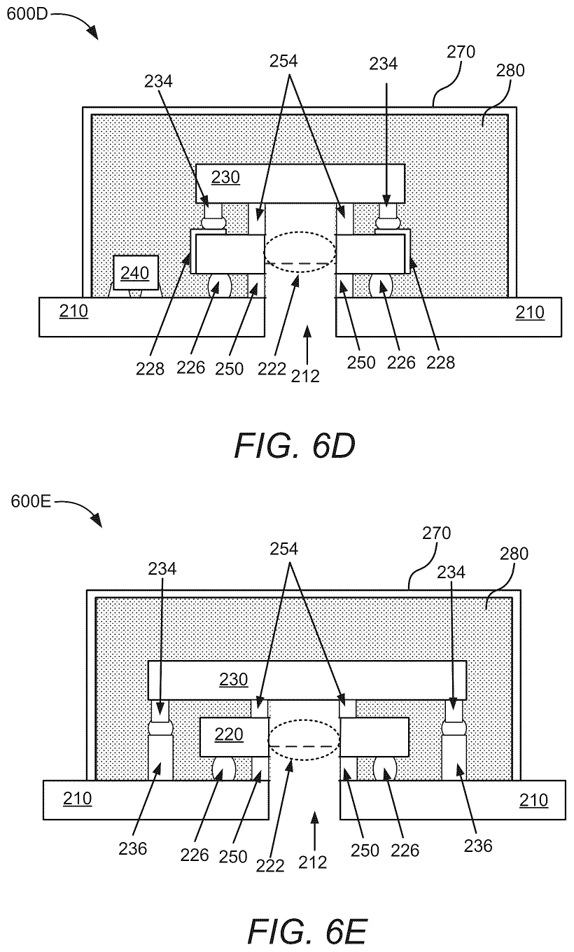

FIGS. 6A-6E illustrate MEMS device examples that may be variations of the MEMS device example 200A of FIG. 2A, according to aspects of the disclosure. Components in FIGS. 6A-6E that are the same or similar to those in FIG. 2A are given the same reference numbers, and detailed description thereof may be omitted.

As shown in FIG. 6A, the MEMS device example 600A may include the MEMS die 220 mounted on the substrate 210, and the IC die 230 may be disposed over the MEMS die 220. In some aspects, the MEMS die 220 may include conductive terminals 228, and the IC die 230 may be coupled to the conductive terminals 228 of the MEMS die 220 via conductive terminals 234 (e.g., solder bumps or copper pillar bumps). In this example, the sealing structure 250 may be coupled to the outer frame structure 224 of the MEMS die 220 and substrate 210.

As shown in FIG. 6B, the MEMS device example 600B may include the MEMS die 220 mounted on the substrate 210, and the IC die 230 may be disposed over the MEMS die 220. In some aspects, compared with the MEMS device example 600A, the IC die 230 in the MEMS device example 600B is not mounted on the MEMS die 220. Instead, the IC die 230 disposed over the MEMS die 220 is mounted on the substrate 210 via conductive terminals 234 (e.g., solder bumps or copper pillar bumps) and/or conductive posts 236 (e.g., copper posts).

As shown in FIG. 6C, the MEMS device example 600C may include the MEMS die 220 mounted on the substrate 210, an interposer 610 on the MEMS die 220, and the IC die 230 may be disposed over the MEMS die 220 and the interposer 610. In some aspects, compared with the MEMS device example 600A, the IC die 230 in the MEMS device example 600C is mounted on the interposer 610 via conductive terminals 238 (e.g., solder bumps or copper pillar bumps), and the interposer 610 is mounted on and electrically coupled to the MEMS die 220.

In some aspects, the functional structure 222 of the MEMS die may be accessible from an upper side or a lower side of the MEMS die 220. Accordingly, the interposer 610 may be configured as another sealing structure covering the upper side of the MEMS die 220.

While FIGS. 6A-6C do not show the passive component 240, the examples shown in FIGS. 6A-6C may still have one or more passive components mounted on the substrate 210. In some aspects, the sealing structure 250 in FIGS. 6A-C and the interposer 610 in FIG. 6C (as another sealing structure) may be configured to block movement of air, a molding compound, and any contaminants from the inner space defined by the conductive shielding structure 270, the sealing structure (e.g., the sealing structure 250 and/or the interposer 610), and the substrate 210 to the functional structure 222 of the MEMS die 220.

As shown in FIG. 6D, the MEMS device example 600D may include the MEMS die 220 mounted on the substrate 210, and the IC die 230 may be disposed over the MEMS die 220. In some aspects, the functional structure 222 of the MEMS die may be accessible from an upper side or a lower side of the MEMS die 220. In some aspects, compared with the MEMS device example 600A, another sealing structure 254 may be formed between the MEMS die 220 and the IC die 230.

As shown in FIG. 6E, the MEMS device example 600E may include the MEMS die 220 mounted on the substrate 210, and the IC die 230 disposed over the MEMS die 220 may be mounted on the substrate 210 via conductive terminals 234 (e.g., solder bumps or copper pillar bumps) and/or conductive posts 236 (e.g., copper posts). In some aspects, the functional structure 222 of the MEMS die 220 may be accessible from an upper side or a lower side of the MEMS die 220. In some aspects, compared with the MEMS device example 600B, another sealing structure 254 may be formed between the MEMS die 220 and the IC die 230.

While FIG. 6D shows the passive component 240, in some applications the MEMS device example 600D may not include the passive component 240. While FIG. 6E does not show the passive component 240, the MEMS device example 600E may still have one or more passive components mounted on the substrate 210. In some aspects in the examples shown in FIGS. 6D-6E, the sealing structure 250 and the sealing structure 254 may be configured to block movement of air, a molding compound, and any contaminants from the inner space defined by the conductive shielding structure 270, the sealing structure 250 and the sealing structure 254, and the substrate 210 to the functional structure 222 of the MEMS die 220.

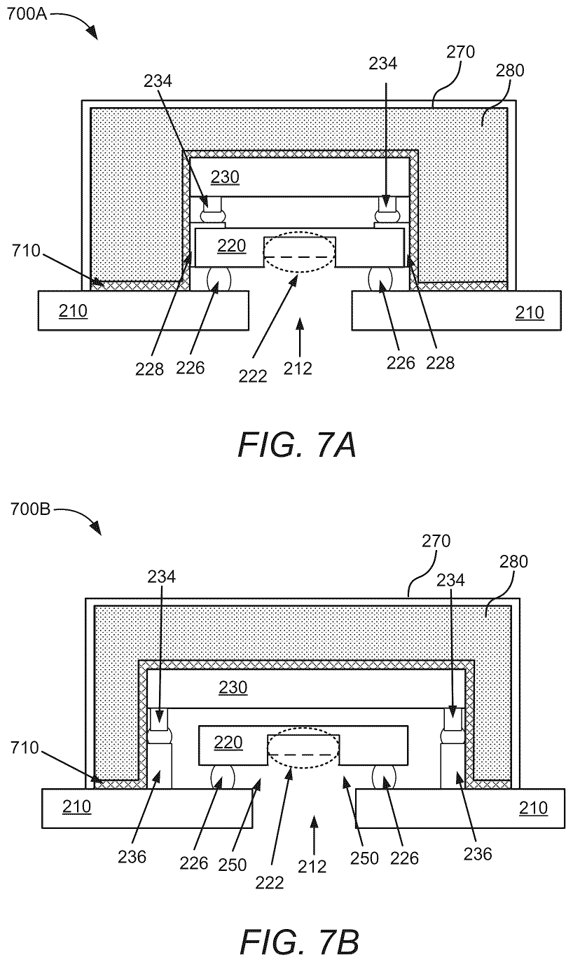

FIGS. 7A-7B illustrate MEMS device examples that may be variations of the example of FIG. 4A, according to aspects of the disclosure. Components in FIGS. 7A-7B that are the same or similar to those in FIG. 4A are given the same reference numbers, and the detailed description thereof may be omitted.

As shown in FIG. 7A, the MEMS device example 700A may include the MEMS die 220 mounted on the substrate 210, and the IC die 230 may be disposed over the MEMS die 220. In some aspects, the MEMS die 220 may include conductive terminals 228, and the IC die 230 may be coupled to the conductive terminals 228 of the MEMS die 220 via conductive terminals 234 (e.g., solder bumps or copper pillar bumps). As shown in FIG. 7A, the MEMS device example 700A does not include the sealing structure 250 between the MEMS die 220 and the substrate 210. Instead, the MEMS device example 700A may include a sealing structure 710 (which may correspond to the sealing structure 410) that may include one or more sealing foils covering the MEMS die 220, at least a portion of the substrate 210 surrounding the MEMS die 220, and/or the IC die 230.

As shown in FIG. 7B, the MEMS device example 700B may include the MEMS die 220 mounted on the substrate 210, and the IC die 230 may be disposed over the MEMS die 220 and mounted on the substrate 210 via conductive terminals 234 (e.g., solder bumps or copper pillar bumps) and/or conductive posts 236 (e.g., copper posts). As shown in FIG. 7B, the MEMS device example 700B does not include the sealing structure 250 between the MEMS die 220 and the substrate 210. Instead, the MEMS device example 700B may include a sealing structure 710 (which may correspond to the sealing structure 410) that may include one or more sealing foils covering the MEMS die 220, at least a portion of the substrate 210 surrounding the MEMS die 220, and/or the IC die 230.

While FIGS. 7A-7B do not show the passive component 240, the examples shown in FIGS. 7A-7B may still have one or more passive components mounted on the substrate 210. In some aspects in the examples shown in FIGS. 7A-7B, the sealing structure 710 may prevent the movement of the molding compound from the inner space defined by the sealing structure 710 and the conductive shielding structure 270 to the functional structure 222 during a compression molding process (for forming the molding compound portion 280).

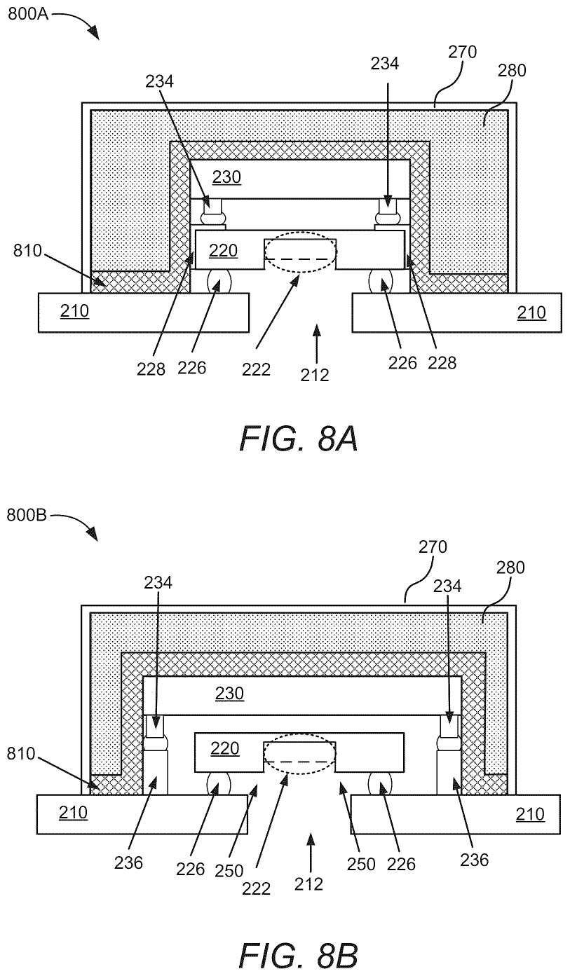

FIGS. 8A-8B illustrate MEMS device examples that may be variations of the example of FIG. 5, according to aspects of the disclosure. Components in FIGS. 8A-8B that are the same or similar to those in FIG. 5 are given the same reference numbers, and the detailed description thereof may be omitted.

As shown in FIG. 8A, the MEMS device example 800A may include the MEMS die 220 mounted on the substrate 210, and the IC die 230 may be disposed over the MEMS die 220. In some aspects, the MEMS die 220 may include conductive terminals 228, and the IC die 230 may be coupled to the conductive terminals 228 of the MEMS die 220 via conductive terminals 234 (e.g., solder bumps or copper pillar bumps). As shown in FIG. 8A, the MEMS device example 800A may include a sealing structure 810 (which may correspond to the sealing structure 510) that may include one or more sheet molding layers covering the MEMS die 220, at least a portion of the substrate 210 surrounding the MEMS die 220, and/or the IC die 230.

As shown in FIG. 8B, the MEMS device example 800B may include the MEMS die 220 mounted on the substrate 210, and the IC die 230 disposed over the MEMS die 220 may be mounted on the substrate 210 via conductive terminals 234 (e.g., solder bumps or copper pillar bumps) and/or conductive posts 236 (e.g., copper posts). As shown in FIG. 8B, the MEMS device example 800B may include a sealing structure 810 (which may correspond to the sealing structure 510) that may include one or more sheet molding layers covering the MEMS die 220, at least a portion of the substrate 210 surrounding the MEMS die 220, and/or the IC die 230.

While FIGS. 8A-8B do not show the passive component 240, the examples shown in FIGS. 8A-8B may still have one or more passive components mounted on the substrate 210. In some aspects in the examples shown in FIGS. 8A-8B, the sealing structure 810 may prevent the movement of the molding compound from the inner space defined by the sealing structure 810 and the conductive shielding structure 270 to the functional structure 222 during a compression molding process or a sheet molding process (for forming the molding compound portion 280).

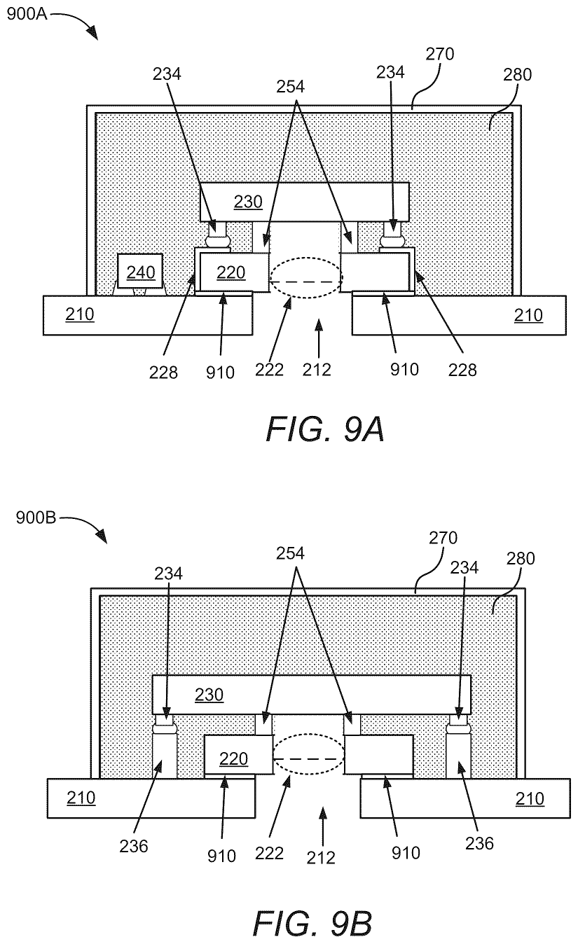

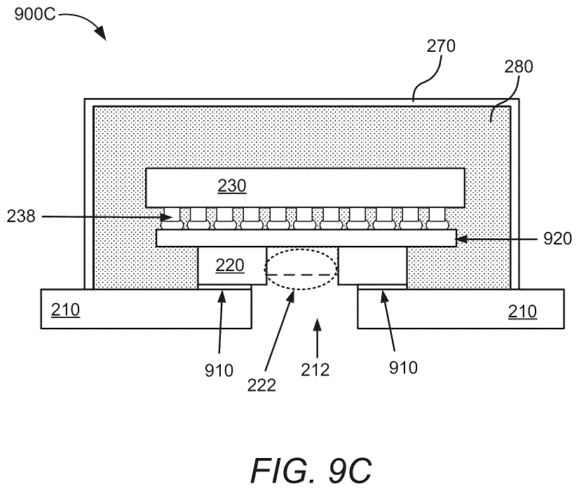

FIGS. 9A-9C illustrate yet another MEMS device examples that may be variations of the example of FIG. 2A, according to aspects of the disclosure. Components in FIGS. 9A-9C that are the same or similar to those in FIG. 2A are given the same reference numbers, and detailed description thereof may be omitted.

As shown in FIG. 9A, the MEMS device example 900A may include the MEMS die 220 mounted on the substrate 210, and the IC die 230 may be disposed over the MEMS die 220. In some aspects, the MEMS die 220 may include conductive terminals 228, and the IC die 230 disposed over the MEMS die 220 may be coupled to the conductive terminals 228 of the MEMS die 220 via conductive terminals 234 (e.g., solder bumps or copper pillar bumps). In some aspects, the MEMS die 220 may be mounted on an upper surface of the substrate 210 at least through an adhesive layer 910 coupling the outer frame structure of the MEMS die 220 (e.g., the outer frame structure 224, not labeled in FIG. 9A) and the substrate 210. In this example, a sealing structure 254 may be formed between the MEMS die 220 and the IC die 230. In some aspects, the sealing structure 254 may have the form as described in FIGS. 3A and 3B and may include a metal material or a polymer material.

As shown in FIG. 9B, the MEMS device example 900B may include the MEMS die 220 mounted on the substrate 210, and the IC die 230 disposed over the MEMS die 220 may be mounted on the substrate 210 via conductive terminals 234 (e.g., solder bumps or copper pillar bumps) and/or conductive posts 236 (e.g., copper posts). In some aspects, like in the MEMS device example 900A, the MEMS die 220 may be mounted on an upper surface of the substrate 210 at least through an adhesive layer 910 coupling the outer frame structure of the MEMS die 220 (e.g., the outer frame structure 224, not labeled in FIG. 9B) and the substrate 210. In this example, a sealing structure 254 may be formed between the MEMS die 220 and the IC die 230. In some aspects, the sealing structure 254 may have the form as described in FIGS. 3A and 3B and may include a metal material or a polymer material.

As shown in FIG. 9C, the MEMS device example 900C may include the MEMS die 220 mounted on the substrate 210, an interposer 920 (which may correspond to the interposer 610 in FIG. 6C) on the MEMS die 220, and the IC die 230 may be disposed over the MEMS die 220 and the interposer 920. In some aspects, the IC die 230 is mounted on interposer 920 via conductive terminals 238 (e.g., solder bumps or copper pillar bumps), and the interposer 920 is mounted on the MEMS die 220. In some aspects, like in the MEMS device example 900A or MEMS device example 900B, the MEMS die 220 may be mounted on an upper surface of the substrate 210 at least through an adhesive layer 910 coupling the outer frame structure of the MEMS die 220 (e.g., the outer frame structure 224, not labeled in FIG. 9B) and the substrate 210. In this example, the interposer 920 may be configured as a sealing structure.

While FIG. 9A shows the passive component 240, in some applications the MEMS device example 900A may not include the passive component 240. While FIGS. 9B and 9C do not show the passive component 240, the MEMS device examples 900B or the MEMS device examples 900C may still have one or more passive components mounted on the substrate 210. In some aspects in the examples shown in FIGS. 9A-9C, the sealing structure 254 in FIGS. 9A-9B or the interposer 920 in FIG. 9C may be configured to block movement of air, a molding compound, and any contaminants from the inner space defined by the conductive shielding structure 270, the sealing structure (e.g., the sealing structure 254 or the interposer 920), and the substrate 210 to the functional structure 222 of the MEMS die 220.

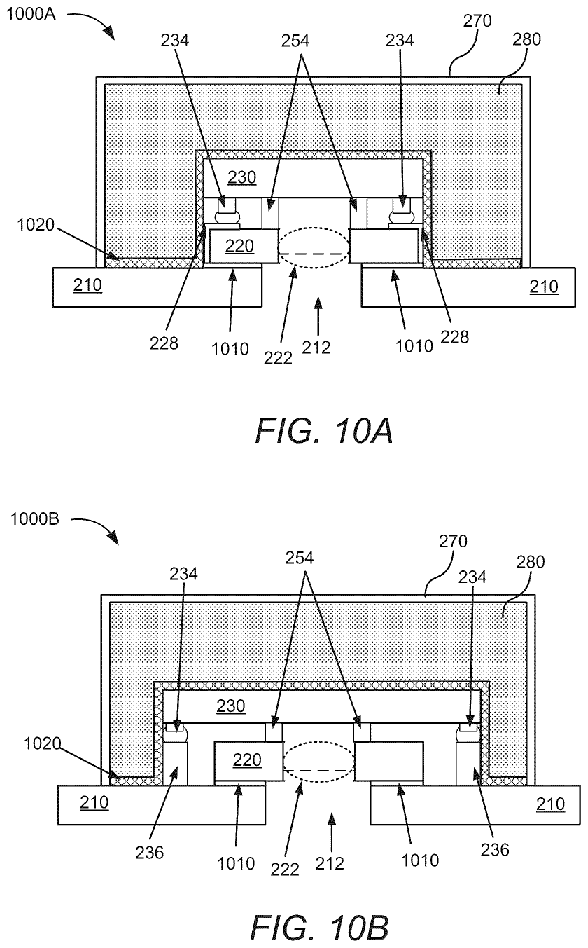

FIGS. 10A-10B illustrate MEMS device examples that may be variations of the example of FIG. 4A, according to aspects of the disclosure. Components in FIGS. 10A-10B that are the same or similar to those in FIG. 4A are given the same reference numbers, and detailed description thereof may be omitted.

As shown in FIG. 10A, the MEMS device example 1000A may include the MEMS die 220 mounted on the substrate 210, and the IC die 230 may be disposed over the MEMS die 220. In some aspects, the MEMS die 220 may include conductive terminals 228, and the IC die 230 may be coupled to the conductive terminals 228 of the MEMS die 220 via conductive terminals 234 (e.g., solder bumps or copper pillar bumps). In some aspects, the MEMS die 220 may be mounted on an upper surface of the substrate 210 at least through an adhesive layer 1010 coupling the outer frame structure of the MEMS die 220 (e.g., the outer frame structure 224, not labeled in FIG. 10A) and the substrate 210. In this example, a sealing structure 1020 (which may be one or more sealing foils and may correspond to the sealing structure 410) may cover the MEMS die 220, the IC die 230, and at least a portion of the substrate 210 surrounding the MEMS die 220. Also, in this example, a sealing structure 254 (which may correspond to the sealing structure 254 in FIG. 9A) may be formed between the MEMS die 220 and the IC die 230.

As shown in FIG. 10B, the MEMS device example 1000B may include the MEMS die 220 mounted on the substrate 210, and the IC die 230 disposed over the MEMS die 220 may be mounted on the substrate 210 via conductive terminals 234 (e.g., solder bumps or copper pillar bumps) and/or conductive posts 236 (e.g., copper posts). In some aspects, the MEMS die 220 may be mounted on an upper surface of the substrate 210 at least through an adhesive layer 1010 coupling the outer frame structure of the MEMS die 220 (e.g., the outer frame structure 224, not labeled in FIG. 10B) and the substrate 210. In this example, a sealing structure 1020 (which may be one or more sealing foils and may correspond to the sealing structure 410) may cover the MEMS die 220, the IC die 230, and at least a portion of the substrate 210 surrounding the MEMS die 220. Also, in this example, a sealing structure 254 (which may correspond to the sealing structure 254 in FIG. 9A) may be formed between the MEMS die 220 and the IC die 230.

While FIGS. 10A-10B do not show the passive component 240, the examples shown in FIGS. 10A-10B may still have one or more passive components mounted on the substrate 210. In some aspects in the examples shown in 10A-10B, the sealing structure 1020 may prevent the movement of the molding compound from the inner space defined by the sealing structure 1020 and the conductive shielding structure 270 to the functional structure 222 during a compression molding process (for forming the molding compound portion 280). In some aspects in the examples shown in FIGS. 10A-10B, the sealing structure 254 may prevent the movement of air or any contaminants from a space between the MEMS die 220 and the IC die 230 to the functional structure 222 during manufacturing or even during the operation of the finished MEMS device examples shown in FIGS. 10A-10B.

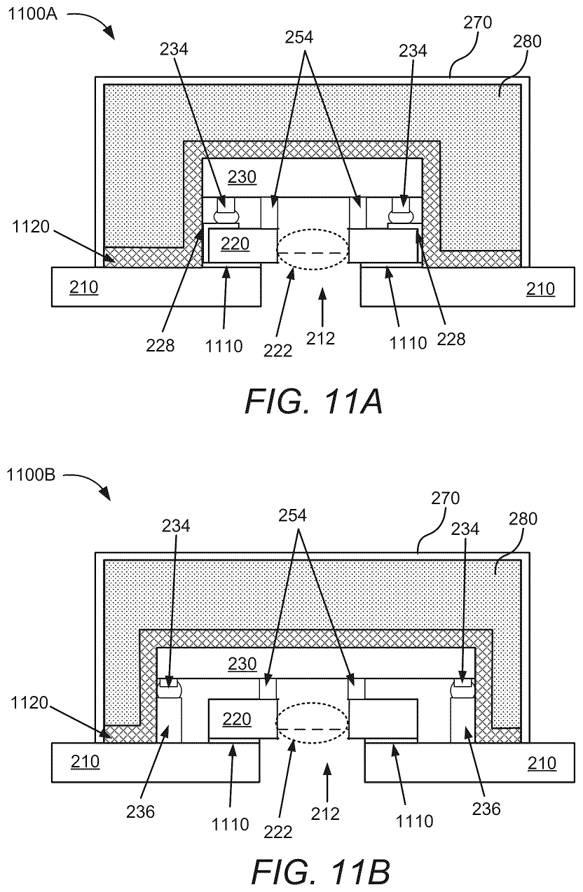

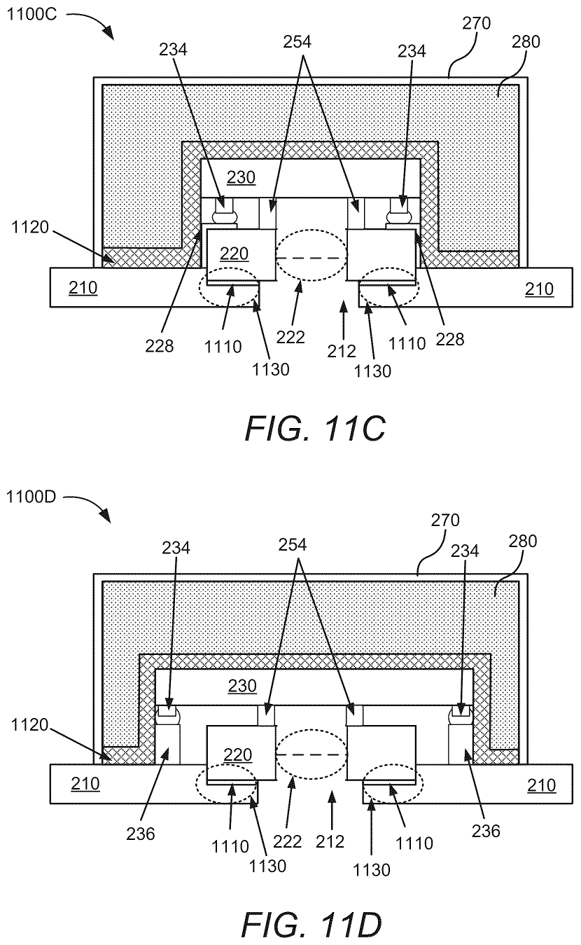

FIGS. 11A-11D illustrate MEMS device examples that may be variations of the example of FIG. 5, according to aspects of the disclosure. Components in FIGS. 11A-11D that are the same or similar to those in FIG. 5 are given the same reference numbers, and detailed description thereof may be omitted.

As shown in FIG. 11A, the MEMS device example 1100A may include the MEMS die 220 mounted on the substrate 210, and the IC die 230 may be disposed over the MEMS die 220. In some aspects, the MEMS die 220 may include conductive terminals 228, and the IC die 230 may be coupled to the conductive terminals 228 of the MEMS die 220 via conductive terminals 234 (e.g., solder bumps or copper pillar bumps). In some aspects, the MEMS die 220 may be mounted on an upper surface of the substrate 210 at least through an adhesive layer 1110 coupling the outer frame structure of the MEMS die 220 (e.g., the outer frame structure 224, not labeled in FIG. 11A) and the substrate 210. In this example, a sealing structure 1120 (which may be one or more sheet molding layers and may correspond to the sealing structure 510) may cover the MEMS die 220, the IC die 230, and at least a portion of the substrate 210 surrounding the MEMS die 220. Also, in this example, a sealing structure 254 (which may correspond to the sealing structure 254 in FIG. 9A) may be formed between the MEMS die 220 and the IC die 230.

As shown in FIG. 11B, the MEMS device example 1100B may include the MEMS die 220 mounted on the substrate 210, and the IC die 230 over the MEMS die 220 may be mounted on the substrate 210 via conductive terminals 234 (e.g., solder bumps or copper pillar bumps) and/or conductive posts 236 (e.g., copper posts). In some aspects, the MEMS die 220 may be mounted on an upper surface of the substrate 210 at least through an adhesive layer 1110 coupling the outer frame structure of the MEMS die 220 (e.g., the outer frame structure 224, not labeled in FIG. 11B) and the substrate 210. In this example, a sealing structure 1120 (which may be one or more sheet molding layers and may correspond to the sealing structure 510) may cover the MEMS die 220, the IC die 230, and at least a portion of the substrate 210 surrounding the MEMS die 220. Also, in this example, a sealing structure 254 (which may correspond to the sealing structure 254 in FIG. 9A) may be formed between the MEMS die 220 and the IC die 230.

FIG. 11C shows a MEMS device example 1100C that may be a variation of the MEM device example 1100A in FIG. 11A. In some aspects, compared with the MEM device example 1100A, the substrate 210 of the MEMS device example 1100C has a recessed portion 1130, and the MEMS die 220 may be mounted on the recessed portion 1130 of the substrate 210 at least through an adhesive layer 1110.

Also, FIG. 11D shows a MEMS device example 1100D that may be a variation of the MEM device example 1100B in FIG. 11B. In some aspects, compared with the MEM device example 1100B, the substrate 210 of the MEMS device example 1100D has a recessed portion 1130, and the MEMS die 220 may be mounted on the recessed portion 1130 of the substrate 210 at least through an adhesive layer 1110.

While FIGS. 11A-11D do not show the passive component 240, the examples shown in FIGS. 11A-11D may still have one or more passive components mounted on the substrate 210. In some aspects in the examples shown in 11A-11D, the sealing structure 1120 may prevent the movement of the molding compound from the inner space defined by the sealing structure 1120 and the conductive shielding structure 270 to the functional structure 222 during a compression molding process or a sheet molding process (for forming the molding compound portion 280). In some aspects in the examples shown in FIGS. 11A-11D, the sealing structure 254 may prevent the movement of air or any contaminants from a space between the MEMS die 220 and the IC die 230 to the functional structure 222 during manufacturing or even during the operation of the finished MEMS device examples shown in FIGS. 11A-11D.

In some aspects, the MEMS device examples shown in FIGS. 6A-11D correspond to having a MEMS die and an IC die disposed stacked one over the other on a substrate. Accordingly, the MEMS device examples shown in FIGS. 6A-11D may also be referred to as based on 2.5D packaging (where D may stand for “dimensions”).

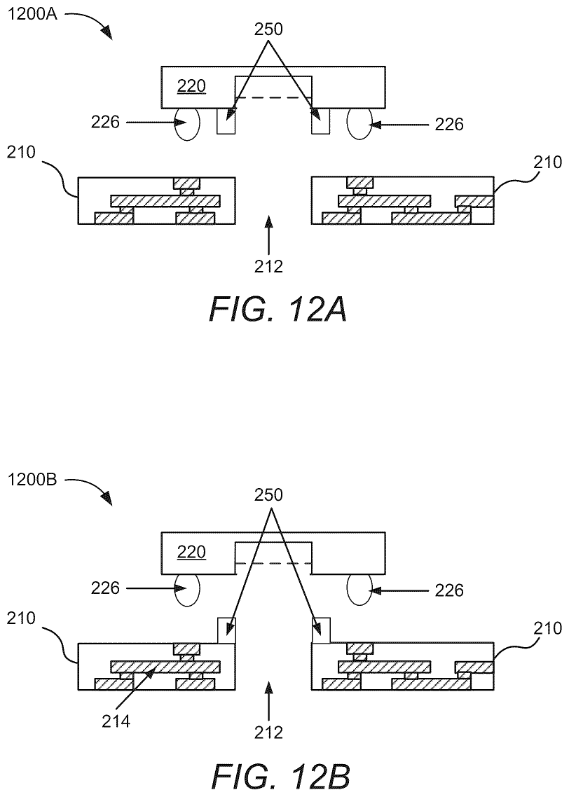

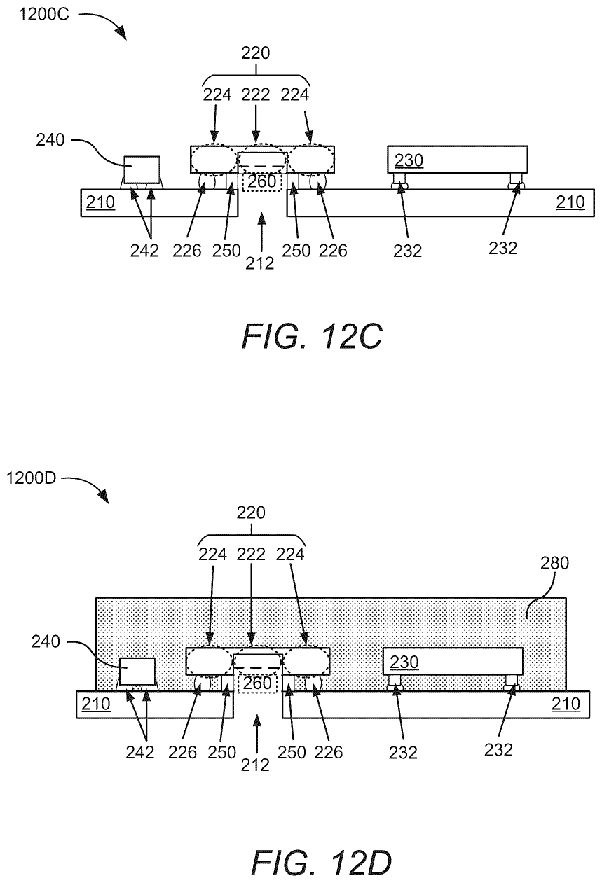

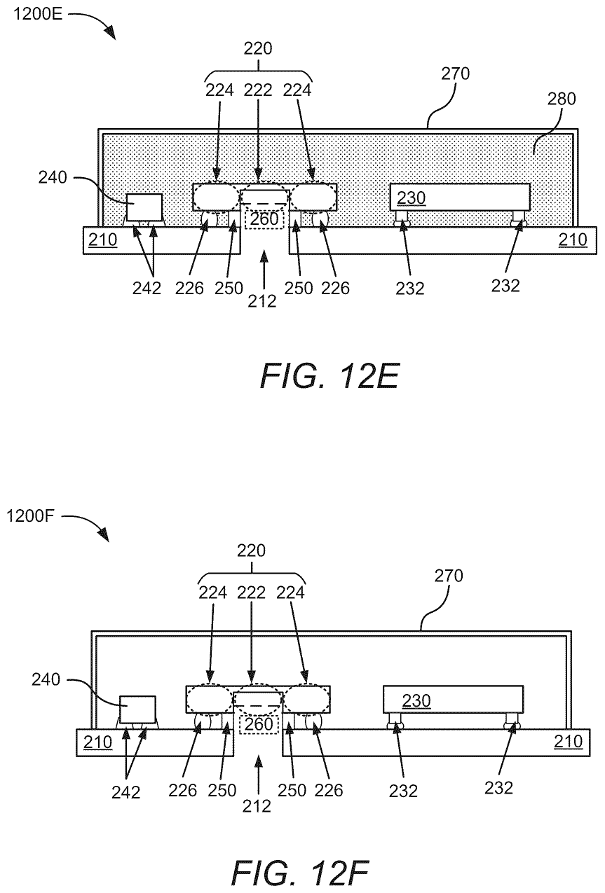

FIGS. 12A-12E illustrate structures at various stages of manufacturing a MEMS device example, such as the MEMS device example 200A of FIG. 2A as a non-limiting example, according to aspects of the disclosure. The components illustrated in FIGS. 12A-12E that are the same or similar to those of FIG. 2A are given the same reference numbers, and the detailed description thereof may be omitted.

As shown in FIG. 12A, a structure 1200A includes a substrate 210 and a MEMS die 220 before the MEMS die 220 being mounted on the substrate 210. In some aspects, the substrate 210 may include an opening 212 defined therein. In some aspects, the MEMS die 220 may include a functional structure (e.g., the functional structure 222, not labeled in FIG. 12A) and an outer frame structure (e.g., the outer frame structure 224, not labeled in FIG. 12A). In some aspects, one or more conductive terminals 226 (e.g., solder bumps or copper pillar bumps) may be formed on a lower surface of the MEMS die 220.

In some aspects, as shown in FIG. 12A, the sealing structure 250 may be formed based on a metal ring or a polymer ring that is formed on the lower surface of the MEMS die 220 before the MEMS die 220 is mounted on the substrate 210. In some aspects, the metal ring to be used as the sealing structure 250 may be formed based on the same process for forming the one or more conductive terminals 226 and thus may be provided in the form of a ring of solder bump or copper pillar bump. In some aspects, the metal ring may include a metal material such as copper. In some aspects, the polymer ring may be formed by depositing or printing a layer of polymer material followed by an etching or patterning process. In some aspects, the polymer material may include an adhesive material or a solder resist material.

As shown in FIG. 12B, a structure 1200B includes a substrate 210 and a MEMS die 220 before the MEMS die 220 being mounted on the substrate 210. In some aspects, as shown in FIG. 12B, the sealing structure 250 may be formed based on a metal ring or a polymer ring that is formed on an upper surface of the substrate 210 before the MEMS die 220 is mounted on the substrate 210. In some aspects, the metal ring to be used as the sealing structure 250 may be formed based on the same process for forming the one or more conductive patterns 214 (e.g., conductive traces and/or conductive vias). In some aspects, the metal ring may include a metal material such as copper. In some aspects, the polymer ring may be formed by depositing or printing a layer of polymer material followed by an etching or patterning process. In some aspects, the polymer material may include an adhesive material or a solder resist material (e.g., having a two-step solder resist configuration).

As shown in FIG. 12C, a structure 1200C may be formed by mounting the MEMS die 220 on the substrate 210 as prepared based on the structure 1200A or the structure 1200B. In some aspects, the IC die 230 and the passive component 240 may be mounted on the substrate 210. In some aspects, the MEMS die 220 may be mounted on the substrate 210 through one or more conductive terminals 226 (e.g., solder bumps or copper pillar bumps) based on SMT. In some aspects, the IC die 230 and the passive component 240 may be mounted on the substrate 210 through one or more conductive terminals 232 and 242 (e.g., solder bumps or copper pillar bumps) based on SMT.

As shown in FIG. 12D, a structure 1200D may be formed based on the structure 1200C by forming a molding compound portion 280 on the substrate 210. In some aspects, the molding compound portion 280 may be formed based on disposing a molding compound on the substrate 210. In some aspects, the molding compound may be disposed based on compression molding.

As shown in FIG. 12E, a structure 1200E may be formed based on the structure 1200D by forming a conductive shielding structure 270 over the substrate 210 and covering the MEMS die 220, the IC die 230, the passive component 240, and the sealing structure 250. In some aspects, the forming the conductive shielding structure 270 may include forming conductive lines, a conductive mesh, or a conductive film over the molding compound portion 280 as the conductive shielding structure 270. In some aspects, the forming the conductive shielding structure 270 may include mounting a conductive cover as the conductive shielding structure 270 on the substrate 210.

In some aspects, the structure 1200E may correspond to the MEMS device example 200A. In some aspects, the conductive shielding structure 270, the sealing structure 250, and the substrate 210 may define an inner space of the MEMS device. In some aspects, the molding compound may be disposed in at least a portion of the inner space as the molding compound portion 280. In some aspects, the sealing structure 250 may be configured to block movement of air or the molding compound from the inner space through the sealing structure 250 to the functional structure 222 of the MEMS die 220. In some aspects, the molding compound portion 280 may be omitted, and the sealing structure may still be configured to block contaminants entering from the inner space through the sealing structure 250 to the functional structure 222 of the MEMS die 220.

In some aspects, one or more of the MEMS device examples 600A-600E and 900A-900C may be manufactured based on stages similar to the stages illustrated in FIGS. 12A-12E, with variations of where the IC die 230 may be mounted, how the MEMS die 220 may be mounted on the substrate 210, and whether to further form a sealing structure 254. In some aspects, the formation of the sealing structure 254 may be similar to the stages illustrated with reference to FIGS. 12A-12C. In some aspects, the formation of the molding compound portion 280 and the conductive shielding structure 270 may be similar to the stages illustrated with reference to FIGS. 12D and 12E.

FIG. 12F in view of FIGS. 12A-12C illustrate structures at various stages of manufacturing a MEMS device example, such as the MEMS device example 200B of FIG. 2B as a non-limiting example, according to aspects of the disclosure. The components illustrated in FIG. 12F that are the same or similar to those of FIG. 2B are given the same reference numbers, and the detailed description thereof may be omitted.

As shown in FIG. 12F, a structure 1200F may be formed based on the structure 1200C by forming a conductive shielding structure 270 over the substrate 210 and covering the MEMS die 220, the IC die 230, the passive component 240, and the sealing structure 250. In some aspects, the forming the conductive shielding structure 270 may include mounting a conductive cover on the substrate 210 as the conductive shielding structure 270. In some aspects, the structure 1200F may correspond to the MEMS device example 200B. In this example, the inner space defined by the conductive shielding structure 270, the sealing structure 250, and the substrate 210 may be free from including the molding compound.

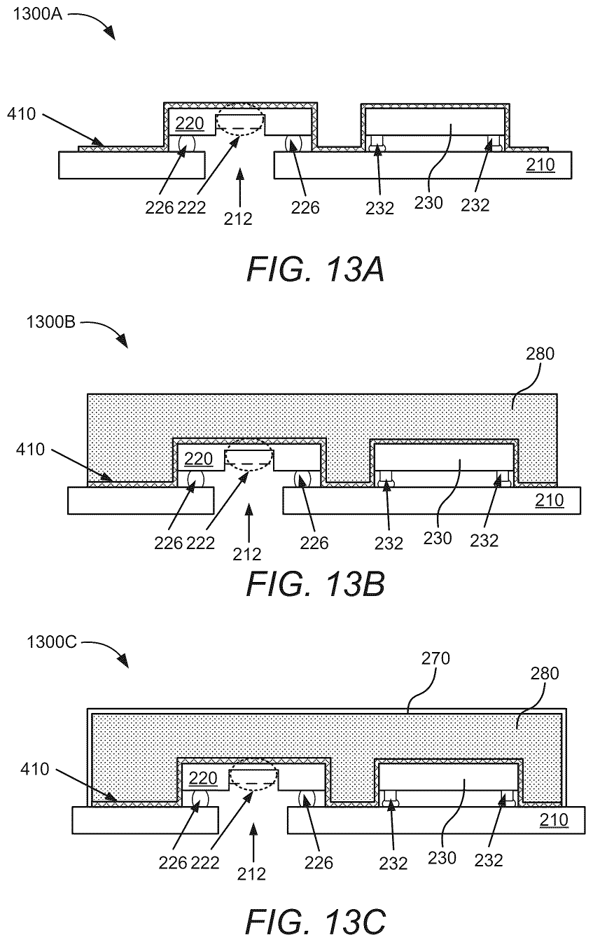

FIGS. 13A-13C in view of FIGS. 12A-12C illustrate structures at various stages of manufacturing a MEMS device example, such as the MEMS device example 400A of FIG. 4A as a non-limiting example, according to aspects of the disclosure. The components illustrated in FIGS. 13A-13C that are the same or similar to those of FIG. 4A are given the same reference numbers, and the detailed description thereof may be omitted.

As shown in FIG. 13A, a structure 1300A may be formed based on the structure 1200C (with the passive component 240 omitted in FIG. 13A) by forming one or more sealing foils covering the MEMS die 220 and at least a portion of the substrate 210 surrounding the MEMS die 220. In some aspects, the one or more sealing foils may be configured as a sealing structure 410.

As shown in FIG. 13B, a structure 1300B may be formed based on the structure 1300A by forming a molding compound portion 280 on the sealing structure 410. In some aspects, the molding compound portion 280 may be formed based on disposing a molding compound on the sealing structure 410. In some aspects, the molding compound may be disposed based on compression molding.

As shown in FIG. 13C, a structure 1300C may be formed based on the structure 1300B by forming a conductive shielding structure 270 over the substrate 210 and covering the MEMS die 220, the IC die 230, and the sealing structure 410. In some aspects, the forming the conductive shielding structure 270 may include forming conductive lines, a conductive mesh, or a conductive film over the molding compound portion 280 as the conductive shielding structure 270. In some aspects, the forming the conductive shielding structure 270 may include mounting a conductive cover on the substrate 210 as the conductive shielding structure 270.

In some aspects, the structure 1300C may correspond to the MEMS device example 400A. In some aspects, the conductive shielding structure 270, the sealing structure 410, and/or the substrate 210 may define an inner space of the MEMS device example 400A. In some aspects, the molding compound may be disposed in at least a portion of the inner space as the molding compound portion 280. In some aspects, the sealing structure 410 may be configured to block movement of air or the molding compound from the inner space through the sealing structure 410 to the functional structure 222 of the MEMS die 220. In some aspects, the molding compound portion 280 may be omitted, and the sealing structure 510 may still be configured to block contaminants entering from the inner space through the sealing structure 410 to the functional structure 222 of the MEMS die 220.

In some aspects, one or more of the MEMS device examples 700A, 700B, 1000A, and 1000B may be manufactured based on stages similar to the stages illustrated in FIGS. 12A-12C and 13A-13C, with variations of where the IC die 230 may be mounted, how the MEMS die 220 may be mounted on the substrate 210, and whether to further form a sealing structure 254. In some aspects, the formation of the sealing structure 254 may be similar to the stages illustrated with reference to FIGS. 12A-12C. In some aspects, the formation of the molding compound portion 280 and the conductive shielding structure 270 may be similar to the stages illustrated with reference to FIGS. 13B and 13C.

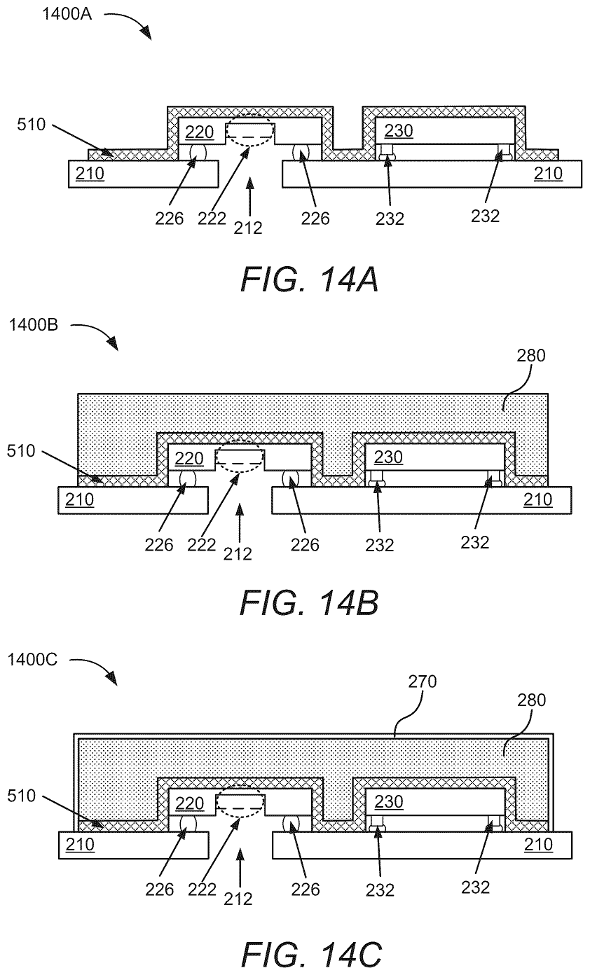

FIGS. 14A-14C in view of FIGS. 12A-12C illustrate structures at various stages of manufacturing a MEMS device example, such as the MEMS device example 500 of FIG. 5 as a non-limiting example, according to aspects of the disclosure. The components illustrated in FIGS. 14A-14C that are the same or similar to those of FIG. 5 are given the same reference numbers, and the detailed description thereof may be omitted.

As shown in FIG. 14A, a structure 1400A may be formed based on the structure 1200C (with the passive component 240 omitted in FIG. 14A) by forming one or more sheet molding layers covering the MEMS die 220 and at least a portion of the substrate 210 surrounding the MEMS die 220. In some aspects, the one or more sheet molding layers may be configured as a sealing structure 510.

As shown in FIG. 14B, a structure 1400B may be formed based on the structure 1400A by forming a molding compound portion 280 on the sealing structure 510. In some aspects, the molding compound portion 280 may be formed based on disposing a molding compound on the sealing structure 510. In some aspects, the molding compound may be disposed based on compression molding or sheet molding with another one or more sheet molding layers.

As shown in FIG. 14C, a structure 1400C may be formed based on the structure 1400B by forming a conductive shielding structure 270 over the substrate 210 and covering the MEMS die 220, the IC die 230, and the sealing structure 510. In some aspects, the forming the conductive shielding structure 270 may include forming conductive lines, a conductive mesh, or a conductive film over the molding compound portion 280 as the conductive shielding structure 270. In some aspects, the forming the conductive shielding structure 270 may include mounting a conductive cover on the substrate 210 as the conductive shielding structure 270.

In some aspects, the structure 1400C may correspond to the MEMS device example 500. In some aspects, the conductive shielding structure 270, the sealing structure 510, and/or the substrate 210 may define an inner space of the MEMS device example. In some aspects, the molding compound may be disposed in at least a portion of the inner space as the molding compound portion 280. In some aspects, the sealing structure 510 may be configured to block movement of air or the molding compound from the inner space through the sealing structure 510 to the functional structure 222 of the MEMS die 220. In some aspects, the molding compound portion 280 may be omitted, and the sealing structure 510 may still be configured to block contaminants entering from the inner space through the sealing structure 510 to the functional structure 222 of the MEMS die 220.

In some aspects, one or more of the MEMS device examples 800A, 800B, and 1100A-1100D may be manufactured based on stages similar to the stages illustrated in FIGS. 12A-12C and 14A-14C, with variations of where the IC die 230 may be mounted, how the MEMS die 220 may be mounted on the substrate 210, and whether to further form a sealing structure 254. In some aspects, the formation of the sealing structure 254 may be similar to the stages illustrated with reference to FIGS. 12A-12C. In some aspects, the formation of the molding compound portion 280 and the conductive shielding structure 270 may be similar to the stages illustrated with reference to FIGS. 14B and 14C.

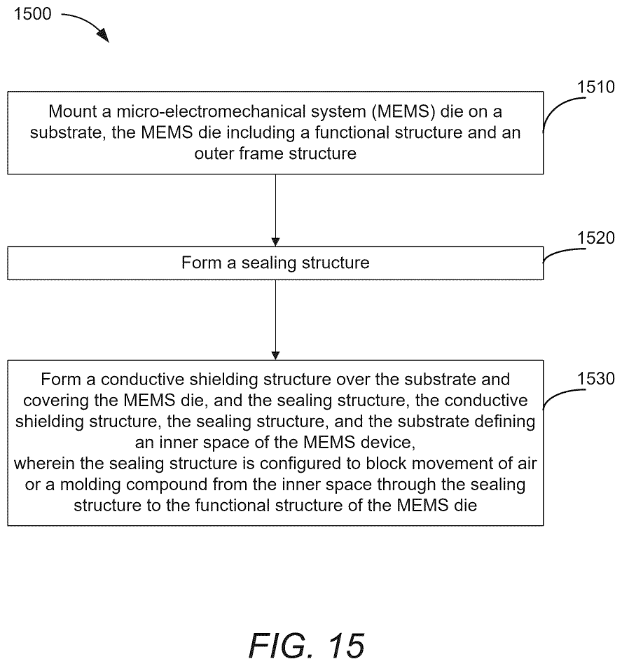

FIG. 15 illustrates a method 1500 of manufacturing a MEMS device (such as the MEMS device examples shown in FIGS. 2A, 2B, and 4A-11D), according to aspects of the disclosure. In some aspects, FIGS. 12A-14C may depict the MEMS device at different stages of manufacturing according to the method 1500.

At operation 1510, a MEMS die (e.g., the MEMS die 220) can be mounted on a substrate (e.g., the substrate 210). In some aspects, the MEMS die may include a functional structure (e.g., the functional structure 222) and an outer frame structure (e.g., the outer frame structure 224).

At operation 1520, a sealing structure can be formed. In some aspects, a metal ring or a polymer ring may be formed on the MEMS die before the MEMS die is mounted on the substrate, and the forming the sealing structure (e.g., the sealing structure 250) may be based on the metal ring or the polymer ring on the MEMS die. In some aspects, a metal ring or a polymer ring may be formed on the substrate before the MEMS die is mounted on the substrate, and the forming the sealing structure (e.g., the sealing structure 250) may be based on the metal ring or the polymer ring on the substrate.

In some aspects, one or more sealing foils or one or more sheet molding layers may be formed to cover the MEMS die and at least a portion of the substrate surrounding the MEMS die, and the one or more sealing foils or the one or more sheet molding layers may be configured as the sealing structure (e.g., the sealing structure 410 or 710 based on one or more sealing foils or the sealing structure 510 or 810 based on one or more sheet molding layers). In some aspects, an interposer may be disposed on the MEMS die and configured as the sealing structure (e.g., the interposer 610 or 920 that is configured as a sealing structure).

At operation 1530, a conductive shielding structure (e.g., the conductive shielding structure 270) may be formed over the substrate and covering the MEMS die and the sealing structure.

In some aspects, prior to the operation 1530 and after the operation 1520, a molding compound may be disposed on the substrate to form a molding compound portion. In some aspects, the molding compound may be disposed based on compression molding or sheet molding. In some aspects, the forming of the conductive shielding structure may include forming conductive lines, a conductive mesh, or a conductive film over the molding compound portion as the conductive shielding structure.

In some aspects, the forming of the conductive shielding structure may include mounting a conductive cover on the substrate as the conductive shielding structure.

In some aspects, the method 1500 may further include mounting an IC die over the MEMS die (e.g., the examples shown in FIGS. 6A-11D). In some aspects, the method 1500 may further include forming a metal ring or a polymer ring on the MEMS die before the IC die is mounted over the MEMS die, and a sealing structure (e.g., as part of the operation 1520 for forming the sealing structure or as an additional operation for forming another sealing structure) between the IC die and the MEMS die may be formed based on the metal ring or the polymer ring (e.g., the sealing structure 254 in FIGS. 6D, 6E, 9A, 9B, and 10A-11D).

In some aspects, the conductive shielding structure, the sealing structure, and the substrate defining an inner space of the MEMS device. In some aspects, the sealing structure may be configured to block movement of air or a molding compound from the inner space through the sealing structure to the functional structure of the MEMS die.

A technical advantage of the method 1500 corresponds to manufacturing a MEMS device that includes a MEMS die and a sealing structure, where the sealing structure may be configured to block movement of air, a molding compound, and/or a contaminant from an inner space of the MEMS device to a functional structure of the MEMS die. Accordingly, packaging a MEMS die based on SMT and molding capsulation may be implemented with the introduction of the sealing structure. In some aspects, the sealing structure may include a metal ring that can be formed together with a conductive pattern or terminal, or a polymer ring that can be formed together with forming a solder resist structure, and thus does not further complicate the manufacturing process of the MEMS device. In some aspects, the sealing structure may include one or more sealing foils or one or more sheet molding layers, which can still minimize the complexity added to the manufacturing process of the MEMS device. Also, the passive components can be incorporated into the MEMS device based on SMT. Accordingly, the MEMS device may be manufactured in a smaller size and can be encapsulated for better contamination and/or moisture resistance with low manufacturing costs.

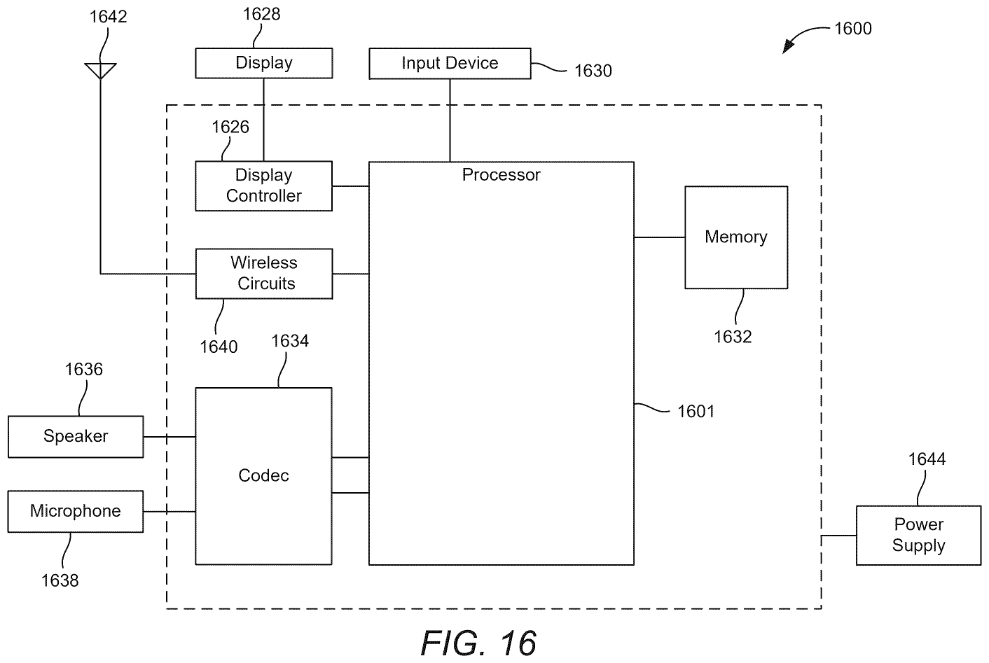

FIG. 16 illustrates a mobile device 1600, according to aspects of the disclosure. In some aspects, the mobile device 1600 may be implemented by including one or more MEMS devices disclosed herein.

In some aspects, mobile device 1600 may be configured as a wireless communication device. As shown, mobile device 1600 includes processor 1601. Processor 1601 may be communicatively coupled to memory 1632 over a link, which may be a die-to-die or chip-to-chip link. Mobile device 1600 also includes display 1628 and display controller 1626, with display controller 1626 coupled to processor 1601 and to display 1628. The mobile device 1600 may include input device 1630 (e.g., physical, or virtual keyboard), power supply 1644 (e.g., battery), speaker 1636, microphone 1638, and wireless antenna 1642. In some aspects, the power supply 1644 may directly or indirectly provide the supply voltage for operating some or all of the components of the mobile device 1600.

In some aspects, FIG. 16 may include coder/decoder (CODEC) 1634 (e.g., an audio and/or voice CODEC) coupled to processor 1601; speaker 1636 and microphone 1638 coupled to CODEC 1634; and wireless circuits 1640 (which may include a modem, RF circuitry, filters, etc.) coupled to wireless antenna 1642 and to processor 1601.

In some aspects, one or more of processor 1601 (e.g., SoCs, application processor (AP)), display controller 1626, memory 1632, CODEC 1634, and wireless circuits 1640 (e.g., baseband interface) may include a MEMS device according to the various aspects described in this disclosure.

It should be noted that although FIG. 16 depicts a mobile device 1600, similar architecture may be used to implement an apparatus including a set top box, a music player, a video player, an entertainment unit, a navigation device, a personal digital assistant (PDA), a fixed location data unit, a computer, a laptop, a tablet, a communications device, a mobile phone, or other similar devices.

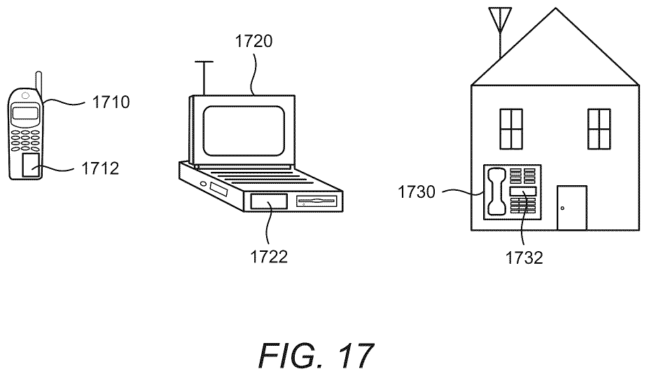

FIG. 17 illustrates various electronic devices 1710, 1720, and 1730 that may incorporate MEMS devices 1712, 1722, and 1732, which may be a MEMS device based on any of the examples described herein, according to aspects of the disclosure.

For example, a mobile phone device 1710, a laptop computer device 1720, and a fixed location terminal device 1730 may each be considered generally user equipment (UE) and may include one or more MEMS devices, such as MEMS devices 1712, 1722, and 1732, and a power supply to provide the supply voltages to power the MEMS devices. The MEMS devices 1712, 1722, and 1732 may be, for example, correspond to a MEMS device manufactured based on the examples described above with reference to FIGS. 2A-14C.

The devices 1710, 1720, and 1730 illustrated in FIG. 17 are merely non-limiting examples. Other electronic devices may also feature the MEMS devices as described in this disclosure, including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device, an access point, a base station, or any other device that stores or retrieves data or computer instructions or any combination thereof.

It will be appreciated that various aspects disclosed herein can be described as functional equivalents to the structures, materials and/or devices described and/or recognized by those skilled in the art. For example, in one aspect, an apparatus may comprise a means for performing the various functionalities discussed above. It will be appreciated that the aforementioned aspects are merely provided as examples and the various aspects claimed are not limited to the specific references and/or illustrations cited as examples.

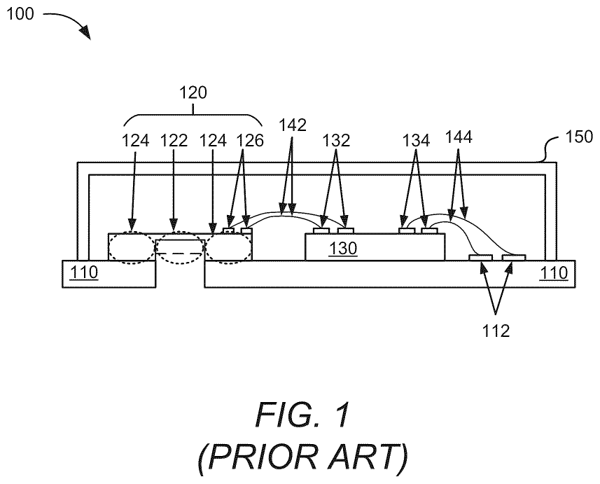

One or more of the components, processes, features, and/or functions illustrated in FIGS. 1-17 may be rearranged and/or combined into a single component, process, feature, or function or incorporated in several components, processes, or functions. Additional elements, components, processes, and/or functions may also be added without departing from the disclosure. In some implementations, FIGS. 1-17 and the corresponding description may be used to manufacture, create, provide, and/or produce integrated devices. In some implementations, a device may include a die, an integrated device, a die package, an IC, a device package, an IC package, a wafer, a semiconductor device, a system in package (SiP), a system on chip (SoC), a package on package (PoP) device, and the like.

In the detailed description above it can be seen that different features are grouped together in examples. This manner of disclosure should not be understood as an intention that the example clauses have more features than are explicitly mentioned in each clause. Rather, the various aspects of the disclosure may include fewer than all features of an individual example clause disclosed. Therefore, the following clauses should hereby be deemed to be incorporated in the description, wherein each clause by itself can stand as a separate example. Although each dependent clause can refer in the clauses to a specific combination with one of the other clauses, the aspect(s) of that dependent clause are not limited to the specific combination. It will be appreciated that other example clauses can also include a combination of the dependent clause aspect(s) with the subject matter of any other dependent clause or independent clause or a combination of any feature with other dependent and independent clauses. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of a clause can be included in any other independent clause, even if the clause is not directly dependent on the independent clause.

Implementation examples are described in the following numbered clauses:

Clause 1. A micro-electromechanical system (MEMS) device, comprising: a substrate; a MEMS die mounted on the substrate, the MEMS die including a functional structure and an outer frame structure; a sealing structure; and a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space to the functional structure of the MEMS die.

Clause 2. The MEMS device of clause 1, wherein the sealing structure has a round shape, a rounded square shape, a square shape, a hexagon shape, or an octagon shape.

Clause 3. The MEMS device of any of clauses 1 to 2, further comprising a molding compound portion that includes the molding compound disposed in at least a portion of the inner space.

Clause 4. The MEMS device of any of clauses 1 to 3, wherein the sealing structure comprises a metal material or a polymer material.

Clause 5. The MEMS device of any of clauses 1 to 4, wherein the sealing structure is coupled to the outer frame structure of the MEMS die and configured to define an access channel through which the functional structure is accessible from inside the MEMS device or from outside of the MEMS device.

Clause 6. The MEMS device of clause 5, wherein the sealing structure is coupled to the outer frame structure of the MEMS die and the substrate.

Clause 7. The MEMS device of clause 5, further comprising: an integrated circuit (IC) die disposed over the MEMS die, wherein the sealing structure is coupled to the outer frame structure of the MEMS die and the IC die.

Clause 8. The MEMS device of clause 1, wherein the sealing structure is coupled to the substrate and configured to cover the MEMS die and at least a portion of the substrate surrounding the MEMS die.

Clause 9. The MEMS device of clause 8, wherein the sealing structure comprises one or more sealing foils or one or more sheet molding layers.

Clause 10. The MEMS device of any of clauses 8 to 9, further comprising: an integrated circuit (IC) die disposed over the MEMS die, wherein the sealing structure is configured to cover the IC die and the MEMS die and at least a portion of the substrate surrounding the IC die and the MEMS die.

Clause 11. The MEMS device of clause 1, further comprising: an integrated circuit (IC) die disposed over the MEMS die, wherein the sealing structure comprises an interposer between the MEMS die and the IC die.

Clause 12. The MEMS device of any of clauses 1 to 11, wherein the MEMS die is electrically coupled to the substrate through one or more solder bumps or copper pillar bumps between the MEMS die and the substrate.

Clause 13. The MEMS device of any of clauses 1 to 11, wherein the MEMS die is mounted on the substrate at least through an adhesive layer coupling the outer frame structure and the substrate.

Clause 14. The MEMS device of clause 1, further comprising: an integrated circuit (IC) die disposed on the substrate, wherein the IC die is electrically coupled to the MEMS die through: first one or more solder bumps or copper pillar bumps between the MEMS die and the substrate, second one or more solder bumps or copper pillar bumps between the IC die and the substrate, and one or more conductive patterns in the substrate.

Clause 15. The MEMS device of clause 1, further comprising: an integrated circuit (IC) die disposed over the MEMS die, wherein the IC die is electrically coupled to the MEMS die through: first one or more solder bumps or copper pillar bumps between the IC die and the MEMS die; second one or more solder bumps or copper pillar bumps between the IC die and the substrate, third one or more solder bumps or copper pillar bumps between the MEMS die and the substrate, and one or more conductive patterns in the substrate; or any combination thereof.

Clause 16. A method of manufacturing a micro-electromechanical system (MEMS) device, comprising: mounting a MEMS die on a substrate, the MEMS die including a functional structure and an outer frame structure; forming a sealing structure; and forming a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space through the sealing structure to the functional structure of the MEMS die.

Clause 17. The method of manufacturing the MEMS device of clause 16, further comprising: disposing the molding compound on the substrate to form a molding compound portion.

Clause 18. The method of manufacturing the MEMS device of clause 17, wherein the disposing the molding compound is based on compression molding or sheet molding.

Clause 19. The method of manufacturing the MEMS device of any of clauses 17 to 18, wherein the forming the conductive shielding structure comprises forming conductive lines, a conductive mesh, or a conductive film over the molding compound portion as the conductive shielding structure.

Clause 20. The method of manufacturing the MEMS device of any of clauses 16 to 19, further comprising: forming a metal ring or a polymer ring on the MEMS die before the MEMS die is mounted on the substrate, and wherein the forming the sealing structure is based on the metal ring or the polymer ring.

Clause 21. The method of manufacturing the MEMS device of any of clauses 16 to 19, further comprising: forming a metal ring or a polymer ring on the substrate before the MEMS die is mounted on the substrate, and wherein the forming the sealing structure is based on the metal ring or the polymer ring.

Clause 22. The method of manufacturing the MEMS device of any of clauses 16 to 19, further comprising: mounting an integrated circuit (IC) die over the MEMS die; and forming a metal ring or a polymer ring on the MEMS die before the IC die is mounted over the MEMS die, wherein the sealing structure is formed between the IC die and the MEMS die based on the metal ring or the polymer ring.

Clause 23. The method of manufacturing the MEMS device of any of clauses 16 to 19, wherein the forming the sealing structure comprises: forming one or more sealing foils or one or more sheet molding layers covering the MEMS die and at least a portion of the substrate surrounding the MEMS die, the one or more sealing foils or the one or more sheet molding layers being configured as the sealing structure.

Clause 24. The method of manufacturing the MEMS device of any of clauses 16 to 23, wherein the forming the conductive shielding structure comprises mounting a conductive cover on the substrate as the conductive shielding structure.

Clause 25. An electronic device, comprising: a micro-electromechanical system (MEMS) device that comprises: a substrate; a MEMS die mounted on the substrate, the MEMS die including a functional structure and an outer frame structure; a sealing structure; and a conductive shielding structure over the substrate and covering the MEMS die and the sealing structure, wherein the conductive shielding structure, the sealing structure, and the substrate define an inner space of the MEMS device, wherein the sealing structure is configured to block movement of air or a molding compound from the inner space through the sealing structure to the functional structure of the MEMS die.

Clause 26. The electronic device of clause 25, wherein the sealing structure has a round shape, a rounded square shape, a square shape, a hexagon shape, or an octagon shape.

Clause 27. The electronic device of any of clauses 25 to 26, further comprising a molding compound portion that includes the molding compound disposed in at least a portion of the inner space.

Clause 28. The electronic device of any of clauses 25 to 27, wherein the sealing structure comprises a metal material or a polymer material.

Clause 29. The electronic device of any of clauses 25 to 28, wherein the sealing structure is coupled to the outer frame structure of the MEMS die and configured to define an access channel through which the functional structure is accessible from inside the MEMS device or from outside of the MEMS device.

Clause 30. The electronic device of any of clauses 25 to 29, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general-purpose processor, a DSP, an ASIC, an FPGA, or other programmable logic device, discrete gate or transistor logic, discrete hardware components, or any combination thereof designed to perform the functions described herein. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in random access memory (RAM), flash memory, read-only memory (ROM), erasable programmable ROM (EPROM), electrically erasable programmable ROM (EEPROM), registers, hard disk, a removable disk, a CD-ROM, or any other form of storage medium known in the art. An example storage medium is coupled to the processor such that the processor can read information from, and write information to, the storage medium. In the alternative, the storage medium may be integral to the processor. The processor and the storage medium may reside in an ASIC. The ASIC may reside in a user terminal (e.g., UE). In the alternative, the processor and the storage medium may reside as discrete components in a user terminal.

In one or more example aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

Furthermore, as used herein, the terms “set,” “group,” and the like are intended to include one or more of the stated elements. Also, as used herein, the terms “has,” “have,” “having,” “comprises,” “comprising,” “includes,” “including,” and the like does not preclude the presence of one or more additional elements (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”) or the alternatives are mutually exclusive (e.g., “one or more” should not be interpreted as “one and more”). Furthermore, although components, functions, actions, and instructions may be described or claimed in the singular, the plural is contemplated unless limitation to the singular is explicitly stated. Accordingly, as used herein, the articles “a,” “an,” “the,” and “said” are intended to include one or more of the stated elements. Additionally, as used herein, the terms “at least one” and “one or more” encompass “one” component, function, action, or instruction performing or capable of performing a described or claimed functionality and also “two or more” components, functions, actions, or instructions performing or capable of performing a described or claimed functionality in combination.

While the foregoing disclosure shows illustrative aspects of the disclosure, it should be noted that various changes and modifications could be made herein without departing from the scope of the disclosure as defined by the appended claims. For example, the functions, steps and/or actions of the method claims in accordance with the aspects of the disclosure described herein need not be performed in any particular order. Further, no component, function, action, or instruction described or claimed herein should be construed as critical or essential unless explicitly described as such.

What is claimed is:

1. A micro-electromechanical system (MEMS) device, comprising:
a substrate;
a MEMS die mounted on the substrate, the MEMS die including a functional structure and an outer frame structure;
a sealing structure; and
a conductive shielding structure over the substrate and covering the MEMS die and the sealing structure, wherein the conductive shielding structure, the sealing structure, and the substrate define an inner space of the MEMS device,
wherein the sealing structure is configured to block movement of air or a molding compound from the inner space to the functional structure of the MEMS die.

2. The MEMS device of claim 1, wherein the sealing structure has a round shape, a rounded square shape, a square shape, a hexagon shape, or an octagon shape.

3. The MEMS device of claim 1, wherein the sealing structure is coupled to the outer frame structure of the MEMS die and configured to define an access channel through which the functional structure is accessible from inside the MEMS device or from outside of the MEMS device.

4. The MEMS device of claim 3, wherein the sealing structure is coupled to the outer frame structure of the MEMS die and the substrate.

5. The MEMS device of claim 3, further comprising:
an integrated circuit (IC) die disposed over the MEMS die,
wherein the sealing structure is coupled to the outer frame structure of the MEMS die and the IC die.

6. The MEMS device of claim 1, wherein the sealing structure is coupled to the substrate and configured to cover the MEMS die and at least a portion of the substrate surrounding the MEMS die.

7. The MEMS device of claim 6, wherein the sealing structure comprises one or more sealing foils or one or more sheet molding layers.

8. The MEMS device of claim 6, further comprising:
an integrated circuit (IC) die disposed over the MEMS die,
wherein:
the sealing structure is configured to cover the IC die and the MEMS die and at least a portion of the substrate surrounding the IC die and the MEMS die, or
the sealing structure comprises an interposer between the MEMS die and the IC die.

9. The MEMS device of claim 1, further comprising:
an integrated circuit (IC) die disposed on the substrate,
wherein the IC die is electrically coupled to the MEMS die through:
first one or more solder bumps or copper pillar bumps between the MEMS die and the substrate,
second one or more solder bumps or copper pillar bumps between the IC die and the substrate, and
one or more conductive patterns in the substrate.

10. The MEMS device of claim 1, further comprising:
an integrated circuit (IC) die disposed over the MEMS die,
wherein the IC die is electrically coupled to the MEMS die through:
first one or more solder bumps or copper pillar bumps between the IC die and the MEMS die;
second one or more solder bumps or copper pillar bumps between the IC die and the substrate, third one or more solder bumps or copper pillar bumps between the MEMS die and the substrate, and one or more conductive patterns in the substrate; or
any combination thereof.

11. A method of manufacturing a micro-electromechanical system (MEMS) device, comprising:
mounting a MEMS die on a substrate, the MEMS die including a functional structure and an outer frame structure;
forming a sealing structure; and
forming a conductive shielding structure over the substrate and covering the MEMS die and the sealing structure, wherein the conductive shielding structure, the sealing structure, and the substrate define an inner space of the MEMS device,
wherein the sealing structure is configured to block movement of air or a molding compound from the inner space through the sealing structure to the functional structure of the MEMS die.

12. The method of manufacturing the MEMS device of claim 11, further comprising:
disposing the molding compound on the substrate to form a molding compound portion.

13. The method of manufacturing the MEMS device of claim 12, wherein the disposing the molding compound is based on compression molding or sheet molding.

14. The method of manufacturing the MEMS device of claim 12, wherein the forming the conductive shielding structure comprises forming conductive lines, a conductive mesh, or a conductive film over the molding compound portion as the conductive shielding structure.

15. The method of manufacturing the MEMS device of claim 11, further comprising:
forming a metal ring or a polymer ring on the MEMS die before the MEMS die is mounted on the substrate, or
forming the metal ring or the polymer ring on the substrate before the MEMS die is mounted on the substrate,
wherein the forming the sealing structure is based on the metal ring or the polymer ring.

16. The method of manufacturing the MEMS device of claim 11, further comprising:
mounting an integrated circuit (IC) die over the MEMS die; and
forming a metal ring or a polymer ring on the MEMS die before the IC die is mounted over the MEMS die,
wherein the sealing structure is formed between the IC die and the MEMS die based on the metal ring or the polymer ring.

17. The method of manufacturing the MEMS device of claim 11, wherein the forming the sealing structure comprises:
forming one or more sealing foils or one or more sheet molding layers covering the MEMS die and at least a portion of the substrate surrounding the MEMS die, the one or more sealing foils or the one or more sheet molding layers being configured as the sealing structure.

18. The method of manufacturing the MEMS device of claim 11, wherein the forming the conductive shielding structure comprises mounting a conductive cover on the substrate as the conductive shielding structure.

19. An electronic device, comprising:
a micro-electromechanical system (MEMS) device that comprises:
a substrate;
a MEMS die mounted on the substrate, the MEMS die including a functional structure and an outer frame structure;
a sealing structure; and
a conductive shielding structure over the substrate and covering the MEMS die and the sealing structure, wherein the conductive shielding structure, the sealing structure, and the substrate define an inner space of the MEMS device,
wherein the sealing structure is configured to block movement of air or a molding compound from the inner space through the sealing structure to the functional structure of the MEMS die.

20. The electronic device of claim 19, wherein the electronic device comprises at least one of: a music player, a video player, an entertainment unit; a navigation device, a communications device, a mobile device, a mobile phone, a smartphone, a personal digital assistant, a fixed location terminal, a tablet computer, a computer, a wearable device, a laptop computer, a server, an internet of things (IoT) device, or a device in an automotive vehicle.
